(19) United States
(12) Patent Application Publication
(10) Pub. No.: US 2005/0169072 A1
(43) Pub. Date: Aug. 4, 2005

(54) Pattern generator, memory controller, and test device

(75) Inventor: Satoru Ohashi, Tokyo (JP)

Correspondence Address: OSHA LIANG L.L.P., 1221 MCKINNEY STREET, SUITE 2800, HOUSTON, TX, 77010, US

(73) Assignee: Advantest Corporation, Tokyo (JP)

(21) Appl. No.: 11/096,690

(22) Filed: Apr. 1, 2005

Related U.S. Application Data
(63) Continuation of application No. PCT/JP03/12574, filed on Oct. 1, 2003.

(30) Foreign Application Priority Data
Oct. 1, 2002 (JP) JP2002-288411

(51) Int. Cl. G11C 7/00

(52) U.S. Cl. 365/201

(57) ABSTRACT

A pattern generator generates a test pattern for testing an electronic device. The pattern generator includes: a main memory for storing test data corresponding to a test pattern; a memory control section for controlling the main memory; and a test pattern output section for receiving the test data from the main memory and outputting a test pattern based on the test data. The memory control section has: a memory sequence storage section for rewritably storing a memory sequence indicating the order to give an input signal to an input pin of the main memory; and a memory access section for receiving the memory sequence from the memory sequence storage section, giving the input signal to the input pin of the main memory according to the memory sequence, and accessing the main memory.

The present application is a continuation application of PCT/JP03/12574 filed on Oct. 1, 2003, claiming priority from a Japanese patent application No. 2002-288411 filed on Oct. 1, 2002, the contents of which are incorporated herein by reference.

### BACKGROUND OF THE INVENTION

1. Field of the Invention

The present invention relates to a pattern generator, a memory controller and a test device. More particularly, the present invention relates to a pattern generator which generates a test pattern for testing an electronic device.

2. Description of Related Art

Conventionally, a pattern generator is used in a test device which tests an electronic device. The pattern generator generates a test pattern, which is an input signal to the electronic device for testing the electronic device. The pattern generator generates the test pattern from test data. The test device includes a main memory storing thereon the test data.

As the main memory, bulk memory, such as a dynamic random access memory, are used, for example. Dynamic random access memories have different interface specifications according to access speed, capacitance, and type.

In the conventional test device, a memory controller, which controls main memory, has been designed corresponding to the interface specification of the dynamic random access memory to be used. Therefore, it has been difficult to change the main memory storing thereon the test data to another memory having different interface specification.

### SUMMARY OF THE INVENTION

Therefore, it is an object of the present invention to provide a pattern generator, a memory controller and a test device which can solve the foregoing problem. The above and other objects can be achieved by combinations described in the independent claims. The dependent claims define further advantageous and exemplary combinations of the present invention.

To accomplish such an object, according to a first aspect of the present invention, there is provided a pattern generator which generates a test pattern for testing an electronic device. The pattern generator includes: a main memory storing thereon test data corresponding to the test pattern; a memory control section which controls the main memory; and a test pattern output section which receives the test data from the main memory, and outputs the test pattern based on the test data, in which the memory control section includes: a memory sequence storage section rewritably storing a memory sequence indicating a sequence to supply an input signal to an input pin of the main memory; and a memory access section which receives the memory sequence from the memory sequence storage section, supplies the input signal to the input pin of the main memory according to the memory sequence, and accesses the main memory.

Moreover, the main memory may be a dynamic random access memory, the memory sequence storage section may store the memory sequence corresponding to at least one of read, write and refresh to the main memory, and the memory access section may access the main memory according to the memory sequence stored on the memory sequence storage section.

Moreover, the test pattern output section may output an access command, which instructs access to the main memory, to the memory control section, the memory control section may further include an access command storage section which stores sequentially the plurality of access commands received from the test pattern output section, and sequentially supply the plurality of access commands stored on the memory access section, and the memory access section may receive the memory sequence for performing the access corresponding to the access command in response to the access command sequentially received from the access command storage section, and access the main memory according to the memory sequence.

Moreover, the test pattern output section may output the access command including an address of the main memory, in which the memory access section may include: a row address generating section rewritably storing thereon correspondence of the access command and the row address of the main memory, and generating the row address corresponding to the access command; a column address generating section rewritably storing thereon correspondence of the access command and the column address of the main memory, and generating the column address corresponding to the access command; and an address signal output section which supplies an address signal to an address input pin of the main memory based on the row address generated by the row address generating section and the column address generated by the column address generating section.

Moreover, the main memory may be a dynamic random access memory; the memory sequence storage section may store the memory sequence corresponding to initialization memory access which initializes the main memory; and the memory access section may initialize the main memory according to a memory sequence corresponding to the initialization memory access.

Moreover, the memory access section may further include a setting information storage section storing thereon information which is to be set to a mode register which sets up operation of the main memory, and the memory access section may set the information to be set to a mode register of the main memory in the memory sequence corresponding to the initialization memory access.

Moreover, the memory access section may set at least one of burst length, lap type, and CAS latency to the mode register.

Moreover, the pattern generator may further include a non-volatile memory storing thereon the memory sequence, and the memory sequence storage section may read the memory sequence from the non-volatile memory, and store it.

According to a second aspect of the present invention, there is provided a memory controller which controls a memory. The memory controller includes; a memory sequence storage section rewritably storing a memory sequence indicating a sequence to supply an input signal to an input pin of the memory; and a memory access section which receives the memory sequence from the memory sequence storage section, supplies the input signal to the input pin of the memory according to the memory sequence, and accesses the memory.

According to a third aspect of the present invention, there is provided a test apparatus which test an electronic device. The test apparatus includes: a main memory storing thereon test data corresponding to a test pattern for testing the electronic device; a memory control section which controls the main memory; a test pattern output section which receives the test data from the main memory, and outputs the test pattern based on the test data; a waveform formatter which formats the test pattern; and a judging section which judges pass/fail of the electronic device based on an output signal output from the electronic device based on the test pattern, in which the memory control section includes: a memory sequence storage section rewritably storing a memory sequence indicating a sequence to supply an input signal to an input pin of the main memory; and a memory access section which receives the memory sequence from the memory sequence storage section, supplies the input signal to the input pin of the main memory according to the memory sequence, and accesses the main memory.

### BRIEF DESCRIPTION OF THE DRAWINGS

FIG. 1 is a drawing exemplary showing a configuration of a test device according to an embodiment of the present invention.

FIG. 2 is a drawing exemplary showing a configuration of a pattern generator.

FIG. 3 is a drawing exemplary showing a detailed configuration of a memory control section.

FIG. 4 is a drawing exemplary showing a memory sequence stored on a memory sequence storage section.

FIG. 5 is a flow chart exemplary showing operation of the memory control section.

### DETAILED DESCRIPTION OF THE INVENTION

The invention will now be described based on the preferred embodiments, which do not intend to limit the scope of the present invention, but exemplify the invention. All of the features and the combinations thereof described in the embodiment are not necessarily essential to the invention.

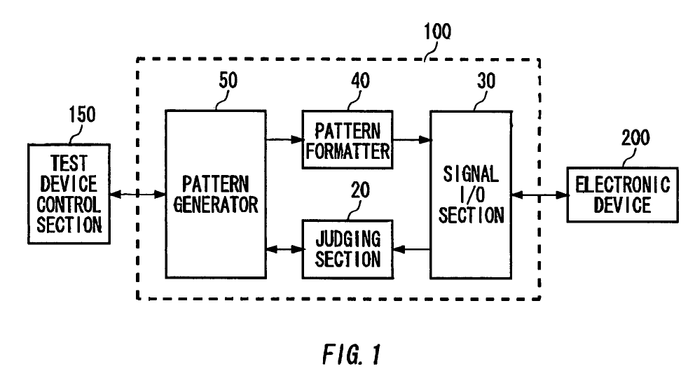

FIG. 1 shows an exemplar configuration of a test device 100 according to an embodiment of the present invention. The test device 100 tests an electronic device 200. The test device 100 includes a pattern generator 50, a pattern formatter 40, a signal I/O section 30, and a judging section 20.

The pattern generator 50 generates a test pattern for testing the electronic device 200 according to an instruction from a test device control section 150 based on the test data stored on an internal main memory. For example, the test device control section 150 is a computer, such as a work station. Moreover, the pattern generator 50 may generate an expected value signal indicating an expected value which is to be output from the electronic device 200 based on the input test pattern. In addition, the main memory may be provided in the test device control section 150. In this case, the pattern generator 50 receives the test data from the test device control section 150.

The pattern formatter 40 receives the test pattern and formats the test pattern. Moreover, the pattern formatter 40 supplies the test pattern, which is received at a desired timing, to the signal I/O section 30.

The signal I/O section 30 supplies the received test pattern to the electronic device 200, and receives the output signal output from the electronic device 200 based on the test pattern. Moreover, the signal I/O section 30 supplies the received output signal to the judging section 20.

The judging section 20 judges pass/fail of the electronic device 200 based on the received output signal. For example, the judging section 20 judges pass/fail of the electronic device 200 by receiving the expected value signal from the pattern generator 50, and comparing the expected value signal and the output signal from the electronic device 200.

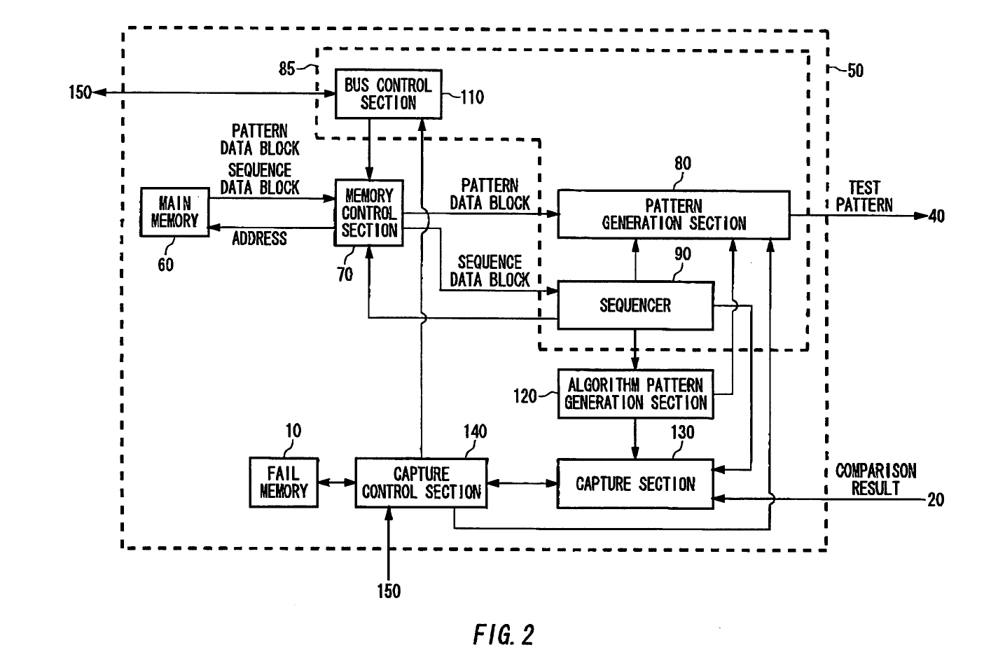

FIG. 2 shows an exemplar configuration of the pattern generator 50. The pattern generator 50 includes a main memory 60, a memory control section 70, a test pattern output section 85, an algorithm pattern generation section 120, a capture section 130, a capture control section 140, and a fail memory 10.

Main memory 60 is a memory storing thereon test data for generating the test pattern. The test data are partitioned and stored into a plurality of test data blocks. For example, the main memory 60 stores: a plurality of pattern data blocks which are partitioned from the pattern data indicating the signal which is to be supplied to the electronic device 200; and sequence data blocks which are partitioned from the sequence data indicating a sequence to supply the pattern data to the electronic device 200, as test data block. Moreover, the main memory 60 associates the pattern data blocks with the sequence data blocks and stores them.

The test pattern output section 85 includes a bus control section 110, a pattern generation section 80, and a sequencer 90. The bus control section 110 receives instruction information, which indicates a sequence to supply test data blocks to the pattern generation section 80 and/or to the sequencer 90, from the test device control section 150. Then, the bus control section 110 sequentially instructs the memory control section 70 which pattern data blocks and/or sequences data block are to be read from the main memory 60. In this case, the bus control section 110 outputs an access command to the memory control section 70 which instructs it to access the main memory 60. The memory control section 70 reads pattern data blocks and sequence data blocks from the main memory 60 sequentially according to the access command received from the bus control section 110. Then, the memory control section 70 supplies the read pattern data blocks to the pattern generation section 80 sequentially, and supplies the read sequence data blocks to the sequencer 90 sequentially.

The pattern generation section 80 receives the pattern data blocks sequentially, and generates a test pattern based on the pattern data blocks. The sequencer 90 stores the received sequence data blocks sequentially, and controls the pattern generation section 80 based on the stored sequence data blocks. For example, the sequence data block is a program for instructing the sequence to output the data of the pattern data blocks and for generating the test pattern, and makes the pattern generation section 80 generate the test pattern according to the program. The sequencer 90 may sequentially instruct the pattern generation section 80 about the address of the pattern data blocks, which is to be received by the pattern generation section 80, based on the sequence data blocks.

Moreover, when the electronic device 200 to be tested is a memory, the sequencer 90 may supply an instruction signal which makes the algorithm pattern generation section 120 generate pattern data for the memory test. The algorithm pattern generation section 120 generates the pattern data for the memory test based on a predetermined algorithm when the instruction signal is received. In this case, the pattern generation section 80 generates the test pattern further based on the pattern data for the memory test.

The capture section 130 and the capture control section 140 store judging result by the judging section 20 in the fail memory 10. The capture section 130 receives either or both of the address of the pattern data blocks which is supplied to the pattern generation section 80 from the sequencer 90, or/and the data for the memory test which is generated by the algorithm pattern generation section 120. The capture section 130 supplies either or both of the address of the corresponding pattern data block or/and the corresponding data for the memory test, to the judging result. The capture control section 140 receives the instructions signal which instructs whether the judging result is to be stored in the fail memory 10 or not from the test device control section 150, and supplies the judging result to the fail memory 10 according to the instructions signal.

Moreover, the capture control section 140 may inform the judging result of the pattern data block concerned to the bus control section 110 when the test of one of the pattern data blocks is completed. In this case, the bus control section 110 informs the judging result to the test device control section 150.

Moreover, the fail memory 10 stores the judging result of the judging section 20. The test device control section 150 may read the judging result stored on the fail memory 10 and analyze the test result of the electronic device 200, or may analyze the test result based on the judging result for every pattern data blocks. Moreover, although the pattern generator 50 includes the fail memory 10 in this example, a pattern generator 50 may omit the fail memory 10, and the test apparatus 100 may include the fail memory 10, or the test device control section 150 may include the fail memory 10 in other examples.

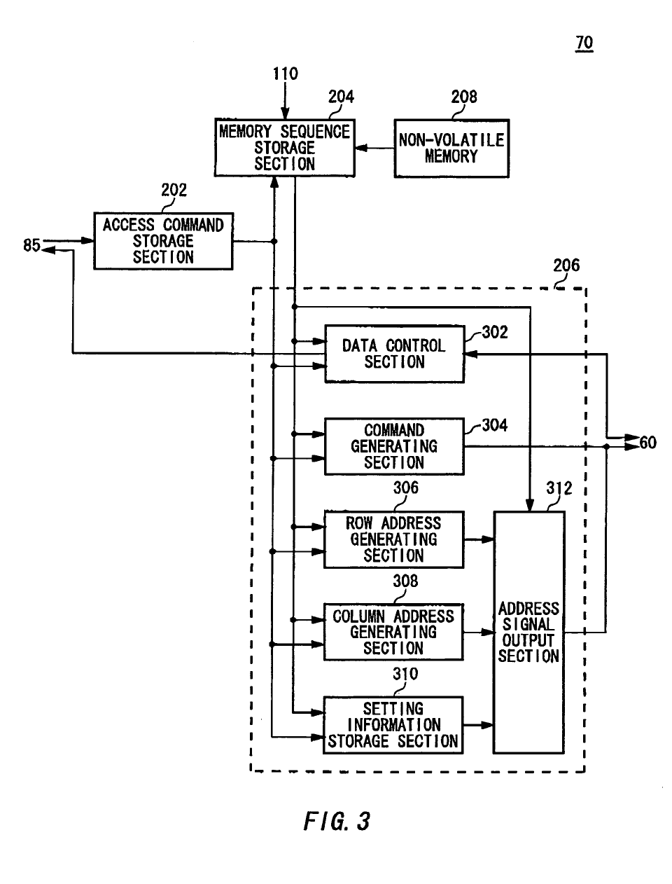

FIG. 3 shows an exemplar detailed configuration of the memory control section 70. The memory control section 70 is a memory controller which controls the main memory 60, and includes a memory sequence storage section 204, an access command storage section 202, a memory access section 206, and a non-volatile memory 208.

Here, in the present embodiment, the main memory 60 is a dynamic random access memory. Moreover, the bus control section 110 (refer to FIG. 2) of the test pattern output section 85 outputs the access command, which includes an address of the main memory 60, to the memory control section 70.

The memory sequence storage section 204 rewritably stores a memory sequence which indicates a sequence to supply input signals to the input pin of the main memory 60. Then, when the memory control section 70 receives an access command from the test pattern output section 85, the memory sequence storage section 204 supplies the memory sequence corresponding to the access command to the memory access section 206.

In addition, in the present embodiment, the memory sequence storage section 204 reads the memory sequence from the non-volatile memory 208 storing thereon memory sequence in advance and stores it. In another example, the memory sequence storage section 204 may receive the memory sequence from the test device control section 150 (refer to FIG. 1), and may store it through the bus control section 110. Moreover, the memory sequence storage section 204 may read a part of the plurality of memory sequences from the non-volatile memory 208, and may receive the other part from the test device control section 150.

The access command storage section 202 is a first in first out (FIFO) memory, stores sequentially a plurality of access commands received from the test pattern output section 85, and sequentially supplies the plurality of stored access commands to the memory access section 206.

The memory access section 206 receives a memory sequence for performing access in response to the access command from the memory sequence storage section 204 according to the access command sequentially received from the access command storage section 202. Then, according to the memory sequence, the memory access section 206 supplies an input signal to the input pin of the main memory 60, and accesses the main memory 60. The memory access section 206 includes a row address generating section 306, a column address generating section 308, a setting information storage section 310, an address signal output section 312, a command generating section 304, and a data control section 302.

The row address generating section 306 generates a row address of the main memory 60 according to the access command, and supplies it to the address signal output section 312. In the present embodiment, the row address generating section 306 rewritably stores correspondence of the access command and the row address of the main memory 60, and generates a row address of the main memory 60 based on this correspondence. The column address generating section 308 generates the column address of the main memory 60 according to the access command, and supplies it to the address signal output section 312. In the present embodiment, the column address generating section 308 rewritably stores correspondence of the access command and the column address of the main memory 60, and generates the column address of the main memory 60 based on this correspondence.

The setting information storage section 310 stores information to be set to a mode register which sets up the operation of the main memory 60. Moreover, the address signal output section 312 receives each of a row address and a column address from each of the row address generating section 306 and the column address generating section 308, and supplies the address signal to the address input pin of the main memory 60 based on the row address and the column address. The address signal output section 312 sets up the mode register of the main memory 60 by further outputting a predetermined signal to the address input pin of the main memory 60.

The command generating section 304 generates a command corresponding to the access command, and supplies the command to the main memory 60 according to the memory sequence. Moreover, the data control section 302 controls input and output of the data signals to/from the data pin of the main memory 60 based on the access command and the memory sequence. Then, the data control section 302 receives test data from the main memory 60, and supplies them to the test pattern output section 85.

As explained above, in the present embodiment, the memory control section 70 reads the test data from the main memory 60 according to the access command, and supplies them to the test pattern output section 85. Thereby, the test pattern output section 85 receives the test data from the main memory 60. Then, the test pattern output section 85 outputs the test pattern based on the test data.

Moreover, in the present embodiment, the memory sequence storage section 204 rewritably stores the memory sequence. Therefore, according to the present embodiment, memory sequences can be changed easily.

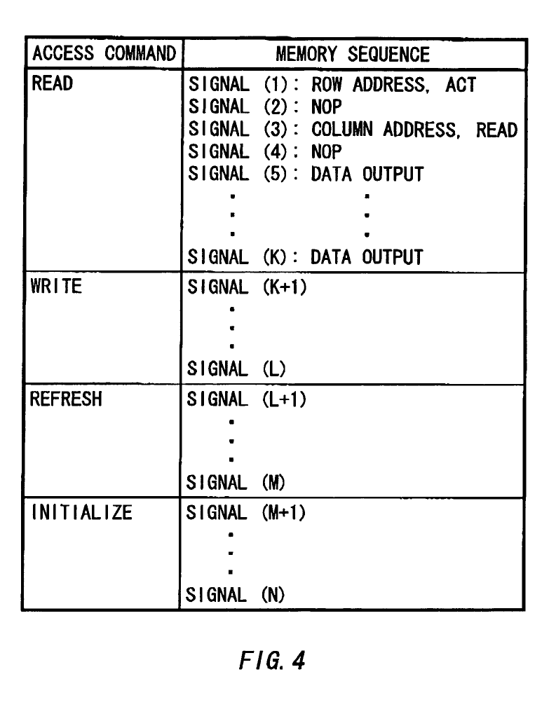

FIG. 4 shows an exemplar memory sequence stored on the memory sequence storage section 204 (refer to FIG. 3). The memory sequence storage section 204 stores a plurality of memory sequences corresponding to a plurality of access commands.

The memory sequence storage section 204 may store memory sequences corresponding to at least one of read, write and refresh to the main memory 60. The memory sequence storage section 204 may store the memory sequences corresponding to initialization memory access which initializes the main memory 60.

Each of the plurality of memory sequences includes a sequence of signals corresponding to the input signals which are to be supplied to the input pin of the main memory 60. For example, as shown in FIG. 4, the memory sequence corresponding to the access command of the read includes Signal (1)-Signal (k), which are the sequence of the signals. The memory sequence storage section 204 supplies each of Signal (1)-Signal (k) to the memory access section 206 sequentially, and the memory access section 206 supplies the input signal corresponding to each of the received Signal (1)-Signal (k) to the input pin of main memory 60. In addition, each of Signal (1)-Signal (k) may be a set of parallel signals which are to be simultaneously supplied to a plurality of input pins of the main memory 60.

In this case, the memory access section 206 (refer to FIG. 3) first supplies a row address and an ACT command to the main memory 60 corresponding to Signal (1), and supplies a column address and a READ command to the main memory 60 corresponding to Signal (3). Then, the memory access section 206 receives data output from the main memory 60 corresponding to Signal (5)-Signal (k). In addition, the memory access section 206 performs NOP corresponding to Signal (2) and Signal (4).

According to the present embodiment, a dynamic random access memory with different interface specification can be accessed by rewriting the memory sequence stored on the memory sequence storage section 204.

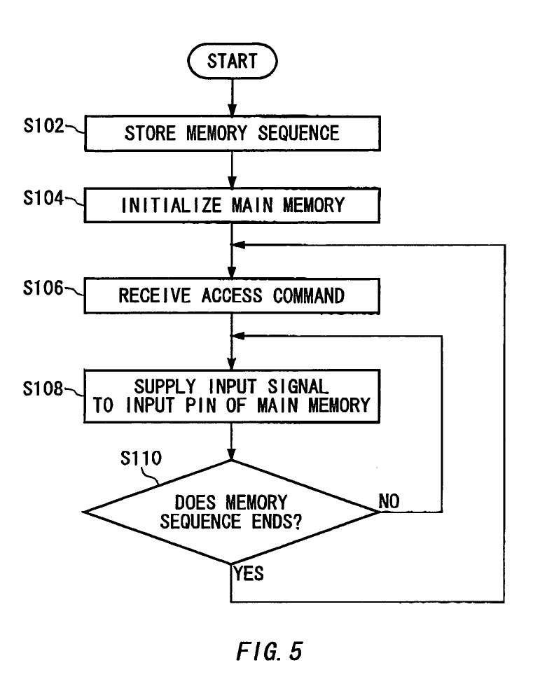

FIG. 5 is a flow chart exemplary showing operation of the memory control section 70. First, the memory sequence storage section 204 reads and stores a memory sequence from the non-volatile memory 208 (S102)

Next, the memory access section 206 initializes the main memory 60 according to the initialization memory sequence corresponding to initialization memory access (S104). Here, the memory access section 206 may set at least one of burst length, lap type, and CAS latency as the mode register of the main memory 60.

Next, each of the command generating section 304, the row address generating section 306, and the column address generating section 308 receives an access command from the test pattern output section 85 through the access command storage section 202, and generates a command, a row address, and a column address, respectively, based on the access command and the memory sequence (S106).

Then, each of the command generating section 304, the address signal output section 312, and the data control section 302 supplies an input signal to the input pin of the main memory 60 according to the memory sequence (S108). In this case, each of the command generating section 304, the address signal output section 312, and the data control section 302 supplies the first signal included in the memory sequence to the input pin of the main memory 60. Moreover, the data control section 302 may receive the data signal output from the main memory 60 according to the memory sequence.

Next, the memory sequence storage section 204 judges whether the memory sequence ends or not (S110). The memory sequence storage section 204 may judge that the memory sequence ends when the last signal is supplied to the main memory 60 among a plurality of signals in the memory sequence in S108.

When the memory sequence ends, the access command storage section 202 receives the next access command from the test pattern output section 85 (S106). When the memory sequence does not end, each of the command generating section 304, the address signal output section 312, and the data control section 302 supplies the following signal included in the memory sequence to the main memory 60 (S108).

In the present embodiment, the memory control section 70 accesses the main memory 60 according to the memory sequence rewritably stored on the memory sequence storage section 204. Therefore, according to the present embodiment, even if the type of the memory used for the main memory 60 is changed, the main memory 60 can be accessed by changing the memory sequence stored on the memory sequence storage section 204. Thereby, the main memory 60 in the test apparatus 100 can be easily changed to a memory having different interface specification.

As is apparent from the description, the memory in the test apparatus or the like can be easily changed to a memory having different interface specification according to the present invention.

Although the present invention has been described by way of an exemplary embodiment, it should be understood that those skilled in the art might make many changes and substitutions without departing from the spirit and the scope of the present invention. It is obvious from the definition of the appended claims that embodiments with such modifications also belong to the scope of the present invention.

1. A pattern generator which generates a test pattern for testing an electronic device, comprising:
a main memory storing thereon test data corresponding to the test pattern;
a memory control section which controls said main memory; and
a test pattern output section which receives the test data from said main memory, and outputs the test pattern based on the test data, wherein
said memory control section comprises:
a memory sequence storage section rewritably storing a memory sequence indicating a sequence to supply an input signal to an input pin of said main memory; and
a memory access section which receives the memory sequence from said memory sequence storage section, supplies said input signal to the input pin of said main memory according to the memory sequence, and accesses said main memory.

2. The pattern generator as claimed in claim 1, wherein
said main memory is a dynamic random access memory,
said memory sequence storage section stores the memory sequence corresponding to at least one of read, write and refresh to said main memory, and
said memory access section accesses said main memory according to the memory sequence stored on said memory sequence storage section.

3. The pattern generator as claimed in claim 1, wherein
said test pattern output section outputs an access command, which instructs access to said main memory, to said memory control section,
said memory control section further comprises an access command storage section which stores sequentially the plurality of access commands received from said test pattern output section, and sequentially supplies the plurality of access commands stored on said memory access section, and
said memory access section receives the memory sequence for performing the access corresponding to the access command in response to the access command sequentially received from said access command storage section, and accesses said main memory according to the memory sequence.

4. The pattern generator as claimed in claim 3, wherein
said test pattern output section outputs the access command including an address of said main memory,
said memory access section comprises:
a row address generating section rewritably storing thereon correspondence of the access command and the row address of said main memory, and generating the row address corresponding to the access command;
a column address generating section rewritably storing thereon correspondence of the access command and the column address of said main memory, and generating the column address corresponding to the access command; and
an address signal output section which supplies an address signal to an address input pin of said main memory based on the row address generated by said row address generating section and the column address generated by said column address generating section.

5. The pattern generator as claimed in claim 1, wherein
said main memory is a dynamic random access memory;
said memory sequence storage section stores the memory sequence corresponding to initialization memory access which initializes said main memory; and
said memory access section initializes said main memory according to a memory sequence corresponding to the initialization memory access.

6. The pattern generator as claimed in claim 5, wherein
said memory access section further comprises a setting information storage section storing thereon information which is to be set to a mode register which sets up operation of said main memory, and
said memory access section sets the information to be set to a mode register of said main memory in the memory sequence corresponding to the initialization memory access.

7. The pattern generator as claimed in claim 6, wherein said memory access section sets at least one of burst length, lap type, and CAS latency to the mode register.

8. The pattern generator as claimed in claim 1, wherein
said pattern generator further comprises a non-volatile memory storing thereon the memory sequence, and
said memory sequence storage section reads the memory sequence from said non-volatile memory, and stores it.

9. A memory controller which controls a memory, comprising:
a memory sequence storage section rewritably storing a memory sequence indicating a sequence to supply an input signal to an input pin of said memory; and
a memory access section which receives the memory sequence from said memory sequence storage section, supplies said input signal to the input pin of said memory according to the memory sequence, and accesses said memory.

10. A test apparatus which test an electronic device, comprising;
a main memory storing thereon test data corresponding to a test pattern for testing the electronic device;
a memory control section which controls said main memory;
a test pattern output section which receives the test data from said main memory, and outputs the test pattern based on the test data;
a pattern formatter which formats the test pattern; and
a judging section which judges pass/fail of the electronic device based on an output signal output from the electronic device based on the test pattern, wherein
said memory control section comprises:
a memory sequence storage section rewritably storing a memory sequence indicating a sequence to supply an input signal to an input pin of said main memory; and
a memory access section which receives the memory sequence from said memory sequence storage section, supplies said input signal to the input pin of said main memory according to the memory sequence, and accesses said main memory.
